(19) United States
(12) Patent Application Publication
(10) Pub. No.: US 2026/0239794 A1
(43) Pub. Date: Aug. 13, 2026

(54) Light emitting module

(71) Applicant: SEOUL VIOSYS CO., LTD., Ansan-si (KR)

(72) Inventor: Jaekwon KIM, Ansan-si (KR)

(73) Assignee: SEOUL VIOSYS CO., LTD., Ansan-si (KR)

(21) Appl. No.: 19/453,731

(22) Filed: Jan. 20, 2026

Related U.S. Application Data
(60) Provisional application No. 63/747,985, filed on Jan. 22, 2025.

(51) Int. Cl. H10H 29/34

(52) U.S. Cl. CPC H10H 29/34

(57) ABSTRACT

A light emitting module includes a support layer and a plurality of light emitting cells spaced apart from one another on a surface of the support layer, in which the surface of the support layer includes village regions in which the light emitting cells are disposed and a street region surrounding the village regions, and a deviation in a width of the street region between adjacent village regions is within 5%.

### TECHNICAL FIELD

The present invention relates to a light emitting module including a plurality of light emitting cells.

### BACKGROUND ART

A light emitting diode (LED) is one of light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these advantages, it has been rapidly replacing a conventional light source. For example, a display apparatus using the light emitting diode may be obtained by forming structures of individually grown red R, green G, and blue B light emitting diodes (LEDs) on a final substrate.

In detail, the light emitting diode is formed by growing epitaxial layers on a substrate, and includes an n-type semiconductor layer, a p-type semiconductor layer, and an active layer interposed therebetween. An n-electrode pad is formed on the n-type semiconductor layer, and a p-electrode pad is formed on the p-type semiconductor layer, so that the light emitting diode is driven by being electrically connected to an external power source through the electrode pads. In this case, current may flow from the p-electrode pad through the semiconductor layers to the n-electrode pad, and light generated through recombination of electrons and holes in the active layer may be emitted.

### DISCLOSURE

### Technical Problem

The present invention aims to provide a light emitting module of a novel structure with improved light emitting performance and reliability.

The present invention aims to provide a light emitting module that is configured to improve reliability by minimizing a defect of a side surface and minimizing leakage current of a light emitting cell even when the light emitting cell is miniaturized.

The present invention aims to provide a light emitting module that is configured to maintain stable and uniform light emitting characteristics without differences in deterioration of individual light emitting cells even during long-term operation by reducing a driving voltage deviation and maintaining a uniform current density between a plurality of light emitting cells.

The present invention aims to provide a light emitting module that is configured to fundamentally reduce a risk of short circuit between electrodes of light emitting cells and a metal migration of a bump.

The present invention aims to provide a light emitting module that is configured to utilize a space between light emitting cells as an air path.

The present invention aims to provide a light emitting module that is configured to effectively block light leaking to a side surface by preventing light leakage through a street region between adjacent light emitting cells and electrodes.

### Technical Solution

An embodiment of the present invention discloses a light emitting module including a support layer and a plurality of light emitting cells spaced apart from one another on one surface of the support layer.

In an embodiment, the one surface of the support layer may include village regions in which the light emitting cells are disposed and a street region surrounding the village regions.

In an embodiment, a deviation in widths of the street region between adjacent village regions may be within 5%.

In an embodiment, the plurality of light emitting cells may be disposed in an N×M matrix form.

In an embodiment, the width of the street region may be 50% or less of a center-to-center distance between the light emitting cells.

In an embodiment, the width of the street region may be 10% or less of a length of one side of the light emitting cell. The width of the street region may be smaller than a height of the light emitting cell.

In an embodiment, a deviation in maximum widths of the light emitting cells may be within 5%.

In an embodiment, a height of the support layer may be 1.5 times or more and 20 times or less than the height of the light emitting cell.

In an embodiment, the light emitting cell may include one or more light emitting structures.

In an embodiment, the light emitting structure may include a first conductivity type semiconductor layer doped with a first conductivity type dopant, a second conductivity type semiconductor layer doped with a second conductivity type dopant, and an active layer disposed between the first conductivity type semiconductor layer and the second conductivity type semiconductor layer.

In an embodiment, the light emitting cell may include a plurality of light emitting structures that are sequentially stacked and emit light of different peak wavelengths from one another.

In an embodiment, an insulation layer covering the light emitting cell may be further included.

In an embodiment, the insulation layer may include a first opening exposing a partial region of the first conductivity type semiconductor layer and a second opening exposing a partial region of the second conductivity type semiconductor layer.

In an embodiment, a first electrode connected to the first conductivity type semiconductor layer through the first opening and a second electrode connected to the second conductivity type semiconductor layer through the second opening may be further included.

In an embodiment, a gap between the first electrode and the second electrode may be 3 μm or more and 8 μm or less.

In an embodiment, a width of the second opening may be 50% or less of the maximum width of the light emitting cell.

In an embodiment, a ratio of a minimum width of the light emitting cell to the width of the street region may be 12.5 or more and 16.5 or less.

In an embodiment, the light emitting module may further include a substrate including a conductive pattern.

In an embodiment, the plurality of light emitting cells may be disposed between the support layer and the substrate.

In an embodiment, the conductive pattern may include a plurality of mounting portions electrically connected to the light emitting cell.

In an embodiment, the plurality of mounting portions may be disposed with rotational symmetry.

In an embodiment, an optical film layer disposed on one surface of the support layer may be further included.

In an embodiment, the optical film layer may be a wavelength conversion layer.

Another embodiment of the present invention discloses a light emitting module including a plurality of light emitting cells spaced apart from one another on one surface of a support layer, in which the one surface of the support layer includes village regions where the light emitting cells are disposed and a street region between village regions, and a width of the street region is 10% or less of a length of one side of the light emitting cell.

### Advantageous Effect

The present invention may provide a light emitting module of a novel structure with improved light emitting performance and reliability.

The present invention may provide a light emitting module that is configured to improve reliability by minimizing a defect of a side surface and minimizing leakage current of a light emitting cell even when the light emitting cell is miniaturized.

The present invention may provide a light emitting module that is configured to maintain stable and uniform light emitting characteristics without differences in deterioration of individual light emitting cells even during long-term operation by reducing a driving voltage deviation and maintaining a uniform current density between a plurality of light emitting cells.

The present invention may provide a light emitting module that is configured to fundamentally reduce a risk of short circuit between electrodes of light emitting cells and a metal migration of a bump.

The present invention may provide a light emitting module that is configured to utilize a space between light emitting cells as an air path.

The present invention may provide a light emitting module that is configured to effectively block light leaking to a side surface by preventing light leakage through a street region and electrodes between adjacent light emitting cells.

### BRIEF DESCRIPTION OF DRAWING

FIG. 1 is a plan view showing a light emitting module according to an embodiment of the present invention.

FIG. 2 is a cross-sectional view in an A-A′ direction of FIG. 1.

FIG. 3 is a plan view showing a light emitting module according to another embodiment of the present invention.

FIG. 4 is a cross-sectional view in a B-B′ direction of FIG. 3.

FIG. 5 is an enlarged view showing a part of a configuration of FIG. 4.

FIG. 6 is a modified example of FIG. 4.

FIG. 7 is another modified example of FIG. 4.

FIG. 8 is a plan view showing shapes of a support layer and a light emitting cell according to an embodiment.

FIG. 9 is a plan view showing shapes of a support layer and a light emitting cell according to another embodiment.

FIG. 10 is a plan view showing shapes of a support layer and a light emitting cell according to another embodiment.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting module of the present invention will be described in detail through accompanying drawings.

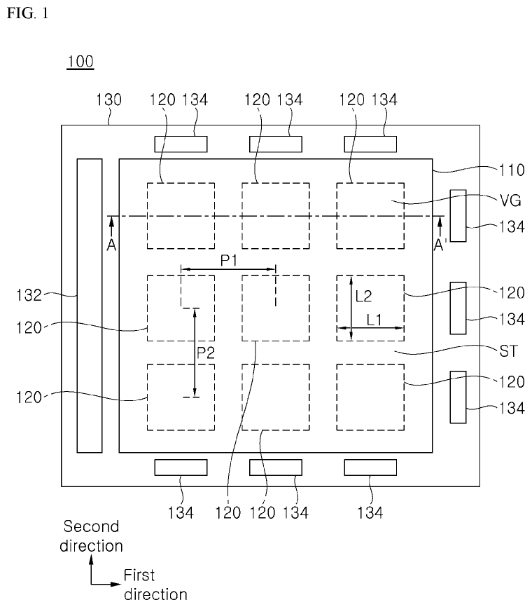

FIG. 1 is a plan view illustrating a light emitting module 100 according to an embodiment of the present invention, and the light emitting module 100 may include a support layer 110 and a plurality of light emitting cells 120 spaced apart from one another on one surface of the support layer 110.

The support layer 110 is not limited to a specific configuration as long as it can support the light emitting cell 120. For example, the support layer 110 may include a support substrate such as a sapphire substrate, a silicon substrate, a silicon carbide substrate, or a spinel substrate. As another example, the support layer 110 may include a substrate such as a gallium nitride substrate, an aluminum nitride substrate, or the like.

In an embodiment, the support layer 110 may be a light-transmitting material that transmits light. For example, the support layer 110 may include at least one of glass, sapphire, polymer, SiO₂, silicone or epoxy.

The support layer 110 may have various shapes. FIG. 1 exemplarily illustrates that the support layer 110 has a rectangular shape, but the shape of the support layer 110 is not limited thereto.

One surface of the support layer 110 may be patterned to form irregularities or protrusions. The irregularities or protrusions may be omitted as an optional configuration.

The plurality of light emitting cells 120 may be disposed on one surface of the support layer 110. The irregularities or protrusions of the support layer 110 may be formed on a surface opposite to the surface on which the light emitting cells 120 are disposed.

A melting region may be formed on an outer surface of the support layer 110. The melting region may include a dark portion with low light transmittance. It is possible to prevent light from leaking on a side surface of the support layer 110 through the dark portion. Through this, a light bleed phenomenon occurring at a side boundary of the light emitting module 100 may be suppressed, and when applied to a light emitting apparatus or the like, it is possible to reduce an optical interference between adjacent light sources and improve a contrast ratio.

The plurality of light emitting cells 120 may be spaced apart on one surface of the support layer 110. An arrangement form of the plurality of light emitting cells 120 may be varied in various ways. For example, the plurality of light emitting cells 120 may be disposed in a form of an N×M matrix (N and M are natural numbers). FIG. 1 illustrates an example in which nine light emitting cells 120 are disposed in a 3×3 matrix form.

The light emitting cell 120 may have various planar shapes. For example, the light emitting cell 120 may have a rectangular planar shape with a first direction side length L1 and a second direction side length L2.

The first direction side length LI of the light emitting cell 120 may be 250 μm or less. The second direction side length L2 of the light emitting cell 120 may be 250 μm or less. The first direction side length L1 may be different from the second direction side length L2.

An area (L1*L2) of the light emitting cell 120 may be 62500 μm² or less. The light emitting cell 120 may have a size that enables a high resolution or high-density integration.

A first direction center-to-center distance P1 of the light emitting cell 120 may be 270 μm or less. A second direction center-to-center distance P2 of the light emitting cell 120 may be 270 μm or less.

Meanwhile, one surface of the support layer 110 may include village regions VG in which the light emitting cells 120 are disposed and a street region ST surrounding the village regions VG.

The village regions VG are regions where the light emitting cells 120 are disposed, and may be provided in a same number as that of light emitting cells 120. The village regions VG may be disposed in a form of an N×M matrix (N and M are natural numbers).

The street region ST is a region surrounding the village regions VG, and one village region VG may have its edges surrounded by the street region ST. The street region ST may be a region that physically or electrically isolates each of the light emitting cells 120. Accordingly, it is possible to prevent a defect that may occur in one light emitting cell 120 from propagating to another adjacent light emitting cell 120, thereby improving a reliability of an entire light emitting module 100.

The street region ST may be in a form of a mesh on a plan view.

In the street region ST, a partial region of one surface of the support layer 110 may be exposed.

A width D2 of the street region ST between adjacent village regions VG may correspond to a separation gap between the adjacent village regions VG. The width D2 of the street region ST may be set in various ways. For example, the width D2 of the street region ST may be within 20 μm.

For example, the width D2 of the street region ST may be 50% or less of the center-to-center distances P1 and P2 between the light emitting cells 120. That is, the side lengths L1 and L2 of the light emitting cell 120 may be greater than or equal to the width D2 of the street region ST. Through this, a ratio of a non-light emitting region (street region) that does not emit light in the entire light emitting module 100 region may be relatively reduced compared to a light emitting region, thereby improving an overall luminance. In a case of a display apparatus, to implement a high-resolution display, a light emitting area may be secured to a maximum extent within a pixel pitch (a center-to-center distance). In addition, it is possible to prevent a decrease in a mechanical strength of the entire light emitting module 100 that may occur due to an excessively wide street region ST, and to prevent a positional shift or damage to the light emitting cell 120 that may occur during a manufacturing process.

Moreover, the width D2 of the street region ST may be 10% or less of one side lengths L1 and L2 of the light emitting cell 120. Through this, a space occupied by the street region ST may be minimized compared to a size of the light emitting cell 120, and a pixel density of the light emitting module 100 may be increased, thereby improving performance and reliability of the light emitting module 100.

By making the width D2 of the street region ST 10% or less of the size of the light emitting cell 120, a larger number of light emitting cells 120 may be integrated in a same area. In addition, high-density integration may be enabled by minimizing the non-light emitting region while securing a minimum physical insulation distance that can prevent short circuits.

A deviation of the widths D2 of the street region ST between adjacent village regions VG may be within 5%. Through this, a uniformity of light emission may be improved throughout the entire region of the light emission module 100. By making the widths D2 of the street region ST substantially similar, shapes and resistances of electrodes 150 and 160 formed in each of the light emitting cells 120 and a heat dissipation path around the light emitting cell 120 may be configured similarly. This may reduce a driving voltage (Vf) deviation between the plurality of light emitting cells 120 and make a current density uniform, thereby suppressing an occurrence of ‘hot spots’ and ensuring stable and uniform light emitting characteristics without differences in deterioration of individual light emitting cells 120 even during long-term operation.

The light emitting module 100 may further include a substrate 130 including a conductive pattern.

The substrate 130 is not limited to a specific type of substrate such as a circuit board, a light-transmitting substrate, a glass substrate, a TFT substrate, a polymer substrate, a flexible substrate, a polyimide substrate, or the like. The substrate 130 may have various planar shapes. The substrate 130 may serve as an interconnection substrate that supplies power from an external driving circuit to distribute to each of the light emitting cells 120, and may be a basis for a mechanical stability of the entire light emitting module 100.

The plurality of light emitting cells 120 may be disposed between the support layer 110 and the substrate 130. The substrate 130 may be opposite to the support layer 110 with the plurality of light emitting cells 120 interposed therebetween. The substrate 130 may be disposed on one side of the plurality of light emitting cells 120 and the support layer 110 may be disposed on the other side.

The substrate 130 may be electrically connected to the plurality of light emitting cells 120 through a conductive pattern. The conductive pattern may include a conductive material.

The substrate 130 may include a plurality of substrate pads 132 and 134 for receiving power from the outside. The substrate pads 132 and 134 may be electrically connected to each of the light emitting cells 120 through the conductive pattern.

For example, at least one of the substrate pads 132 and 134 may be a common pad 132 commonly connected to the plurality of light emitting cells 120. Some of the substrate pads 132 and 134 may be individual pads 134 individually connected to each of the light emitting cells 120. Through this, a turn-on and off of each of the light emitting cells 120 may be individually controlled. Such an electrode connection structure enables matrix driving, thereby enabling an independent and precise control of the brightness of each of the light emitting cells 120 even in a complex light emitting system.

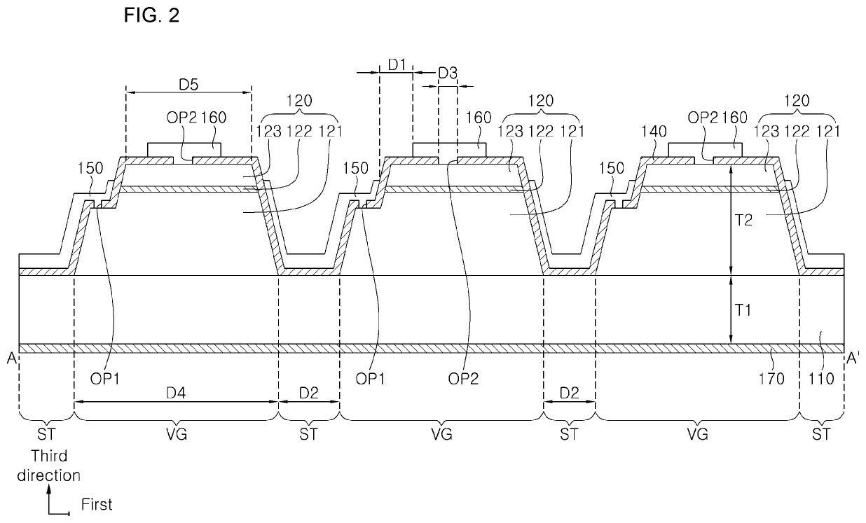

FIG. 2 is a cross-sectional view in an A-A′ direction of the light emitting module 100 of FIG. 1, which illustrates a cross-sectional structure of the light emitting cell 120.

The light emitting cell 120 may include one or more light emitting structures. For example, the light emitting structure may include a first conductivity type semiconductor layer 121 doped with a first conductivity type dopant, a second conductivity type semiconductor layer 123 doped with a second conductivity type dopant, and an active layer 122 disposed between the first conductivity type semiconductor layer 121 and the second conductivity type semiconductor layer 123.

The first conductivity type semiconductor layer 121 may be a semiconductor layer disposed on one surface of the support layer 110, and may include a phosphide or nitride semiconductor such as (Al, Ga, In)P or (Al, Ga, In)N. In addition, the first conductivity type semiconductor layer 121 may be doped as an n-type by including one or more impurities such as Si, C, Ge, Sn, Te, Pb, or others. The present invention is not limited thereto, and as another example, the first conductivity type semiconductor layer 121 may be doped with an opposite conductivity type, including a p-type dopant. Moreover, the first conductivity type semiconductor layer 121 may be formed as a single layer or multiple layers.

The second conductivity type semiconductor layer 123 may include a phosphide or nitride semiconductor such as (Al, Ga, In)P or (Al, Ga, In)N. The second conductivity type semiconductor layer 123 may be doped with a conductivity type opposite to that of the first conductivity type semiconductor layer 121. For example, the second conductivity type semiconductor layer 123 may be doped as a p-type by including an impurity such as Mg.

The active layer 122 is a light emitting layer disposed between the first conductivity type semiconductor layer 121 and the second conductivity type semiconductor layer 123, may include a phosphide or nitride semiconductor such as (Al, Ga, In)P or (Al, Ga, In)N, and may be grown on the first conductivity type semiconductor layer 121 using a technique such as MOCVD, MBE, HVPE, or the like.

In addition, the active layer 122 may include a quantum well structure (QW) including at least two barrier layers and at least one well layer. Furthermore, the active layer 122 may include a multi quantum well structure (MQW) including a plurality of barrier layers and a plurality of well layers. A wavelength of light emitted from the active layer 122 may be adjusted by controlling a composition ratio of materials forming the well layer. In this case, the well layers may include a same element in common, for example, In.

A light exiting surface through which light is emitted may be formed on a side of the first conductivity type semiconductor layer 121 or the second conductivity type semiconductor layer 123. For example, light generated in the active layer 122 may be emitted to the outside through the first conductivity type semiconductor layer 121, or may be emitted to the outside through the second conductivity type semiconductor layer 123. Irregularities or protrusions may be formed on one surface of the first conductivity type semiconductor layer 121 or one surface of the second conductivity type semiconductor layer 123 so as to increase light extraction efficiency.

The village region VG of the support layer 110 may be adjacent to or in contact with the first conductivity type semiconductor layer 121 of the light emitting cell 120. For example, the village region VG may be in contact with a gallium nitride material of the first conductivity type semiconductor layer 121. Accordingly, it is possible to prevent light loss and leakage while light generated in the light emitting cell 120 enters the support layer 110.

In addition, by minimizing a difference in refractive indices between the support layer 110 and the first conductivity type semiconductor layer 121, Fresnel reflection on an interface may be reduced, and generated light may be made to be transmitted to the support layer 110 without loss.

Since the support layer 110 is adjacent to or in contact with the light emitting cell 120 in the village region VG, a difference in refractive indices of the interface in the village region VG (a difference in a refractive index of the support layer 110 and a refractive index of the light emitting cell 120) may be different from a difference in refractive indices of the interface in the street region ST (a difference in the refractive index of the support layer 110 and a refractive index of air, or a difference in the refractive index of the support layer 110 and a refractive index of an insulation layer 140 which will be described later).

Meanwhile, each of the light emitting cells 120 may emit light of substantially a same peak wavelength. As another example, at least one of the plurality of light emitting cells 120 may emit light of a different peak wavelength than those of the other light emitting cells 120.

The light emitting cell 120 may have a maximum width D4 and a minimum width D5 in cross section. For example, the maximum width D4 of the light emitting cell 120 may correspond to a width of one surface of the light emitting cell 120 facing the support layer 110. In addition, the minimum width D5 of the light emitting cell 120 may correspond to a width of one surface of the light emitting cell 120 facing the substrate 130. A lowermost end of the light emitting cell 120 may be in contact with the support layer 110. The maximum width D4 may be equal to the side lengths L1 and L2 of the light emitting cell 120 of FIG. 1. In another embodiment, the maximum width D4 of the light emitting cell 120 may correspond to the width of one surface of the light emitting cell 120 facing the substrate 130, and the minimum width D5 of the light emitting cell 120 may correspond to the width of one surface of the light emitting cell 120 facing the support layer 110.

A deviation of the maximum widths D4 of the light emitting cells 120 may be within 5%. Through this, deviations of current densities and driving voltages (Vf) between the plurality of light emitting cells 120 may be reduced, and stable and uniform light emitting characteristics may be maintained without differences in deterioration of individual light emitting cells 120 even during long-term operation.

A ratio of the minimum width D5 of the light emitting cell 120 to the width D2 of the street region ST may be 12.5 or more and 16.5 or less. In a case that the ratio is less than 12.5 (i.e., in a case that the width D2 of the street region ST is excessively large), a density of the light emitting cell 120 may be low, thereby decreasing luminous intensity. In a case that the ratio exceeds 16.5 (i.e., in a case that the width D2 of the street region ST is excessively small), a possibility of a short circuit between the light emitting cells 120 increases, thereby increasing a defect rate.

Referring again to FIG. 2, the width D2 of the street region may be smaller than a height T2 of the light emitting cell 120.

A height T1 of the support layer 110 may be 1.5 times or more and 20 times or less than the height T2 of the light emitting cell 120. For example, the height T1 of the support layer 110 may be 500 μm or less. However, the inventive concepts are not necessarily limited thereto, and the height T1 of the support layer 110 may be smaller than the height of the light emitting cell 120.

Meanwhile, the light emitting module 100 may further include the insulation layer 140 covering the light emitting cell 120. The insulation layer 140 may include various insulation materials. For example, the insulation layer 140 may be a layer including at least one of SiO₂, TiO₂, Al₂O₃, AlN, HfO₂, ZrO₂, MgO, Polyimide, epoxy, Silicone, Benzocyclobutene or SiN. In a case that the insulation layer 140 include both SiO₂ and SiN, optical characteristics may be optimized and a stability of a thin film may be improved by using different characteristics (e.g., refractive index, stress characteristics) that each material has.

The insulation layer 140 may cover the plurality of light emitting cells 120 and the street region ST. That is, the insulation layer 140 may continuously cover the plurality of light emitting cells 120, and may extend from the light emitting cells 120 to the street region ST to cover the street region ST.

The insulation layer 140 may include a first opening OP1 that exposes a partial region of the first conductivity type semiconductor layer 121. The insulation layer 140 may further include a second opening OP2 that exposes a partial region of the second conductivity type semiconductor layer 123.

The first opening OP1 or second opening OP2 may be disposed corresponding to each of the light emitting cells 120. The second opening OP2 may be disposed on an upper surface of the light emitting cell 120, and the first opening OP1 may be spaced apart from the second opening OP2. However, the inventive concepts are not necessarily limited thereto, and the first opening OP1 and the second opening OP2 may be overlapped at least partially in a thickness direction.

The light emitting module 100 may include a first electrode 150 connected to the first conductivity type semiconductor layer 121 through the first opening OP1 and a second electrode 160 connected to the second conductivity type semiconductor layer 123 through the second opening OP2.

The first electrode 150 and the second electrode 160 may be provided for each of the light emitting cells 120.

The first electrode 150 may cover the street region ST and extend to a side surface of an adjacent light emitting cell 120. The first electrode 150 may extend to a height higher than the active layer 122 of the light emitting cell 120. Light emitted from the active layer 122 may be reflected by the first electrode 150 and emitted through a light exiting surface, and accordingly, light extraction efficiency may be increased. In addition, the first electrode 150 covers the street region ST, so it may perform a role as a light blocking wall that physically blocks light leaking into adjacent light emitting cells 120, thereby suppressing optical interference.

The second electrode 160 may be disposed on the upper surface of the light emitting cell 120.

A gap DI between the first electrode 150 and the second electrode 160 may be 3 μm or more and 8 μm or less. A space formed by the gap DI between the first electrode 150 and the second electrode 160 may be an air path. The air pass may form an air layer between the two electrodes 150 and 160 to secure an insulation distance and prevent an infiltration of moisture or contaminants, thereby reducing a risk of a short circuit between the electrodes 150 and 160.

A width D3 of the second opening OP2 may be 50% or less of the light emitting cell 120. Through this, even when the light emitting cell 120 is miniaturized, a defect on a side surface of the light emitting cell 120 may be minimized and leakage current of the light emitting cell 120 through the second electrode 160 may be minimized, thereby improving reliability. On the side surface of the light emitting cell 120, a crystalline defect is likely to occur due to damage during processes such as etching. When the second electrode 160 is in direct contact with such a defective region, a significant leakage current may occur, which may cause a decrease in an efficiency and shorten a lifespan of the light emitting cell 120. The present invention may block such a leakage current path by having the second electrode 160 contact only a central region which has a few defects.

Optionally, the light emitting module 100 may further include an optical film layer 170 disposed on one surface of the support layer 110. The optical film layer 170 may be disposed on a surface opposite to one surface of the support layer 110 on which the light emitting cells 120 are disposed.

For example, the optical film layer 170 may be a wavelength conversion layer. The wavelength conversion layer may include a wavelength conversion material. For example, white light may be implemented when using a wavelength conversion layer including a yellow phosphor together with a light emitting cell 120 that emits blue light.

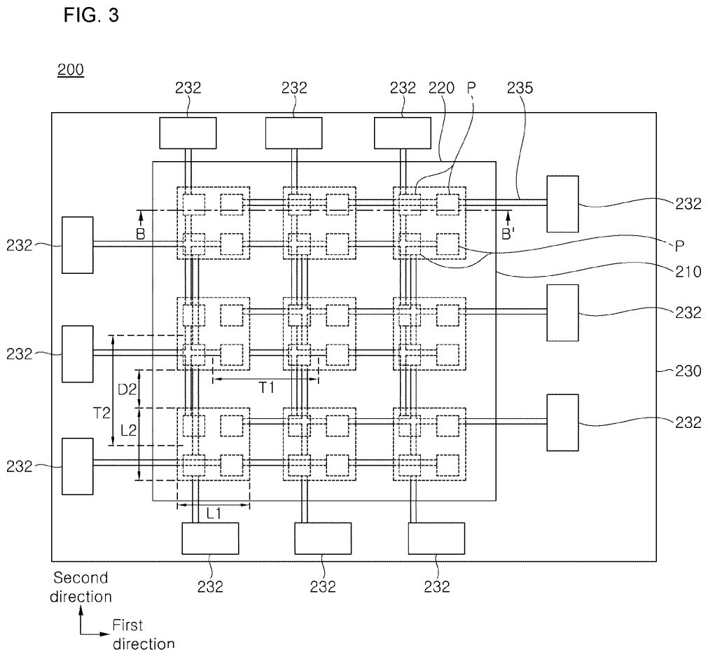

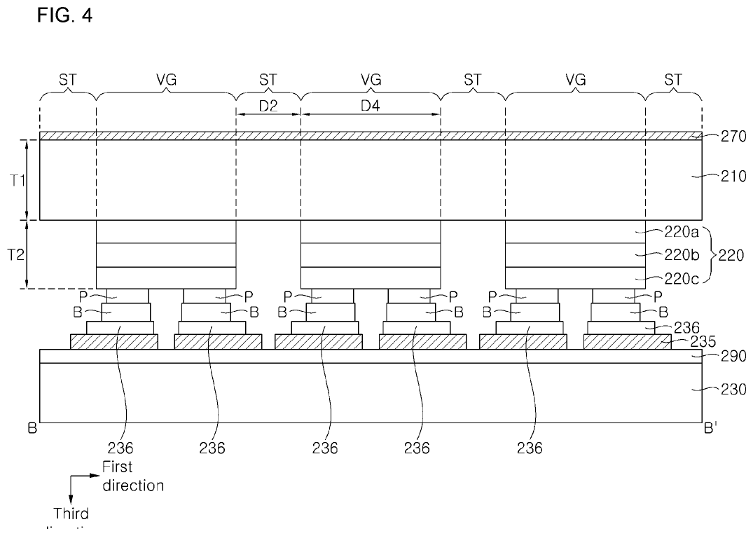

FIG. 3 is a plan view illustrating a light emitting module 200 according to another embodiment of the present invention, and FIG. 4 is a cross-sectional view in a B-B′ direction of the light emitting module 200 of FIG. 3. The light emitting module 200 of FIG. 3 and FIG. 4 will be described in detail, focusing on differences from the light emitting module 100 of FIG. 1 and FIG. 2.

The light emitting module 200 may include a support layer 210 and a plurality of light emitting cells 220 spaced apart from one another on one surface of the support layer 210. The support layer 210 may be configured identically as the support layer 110 of the light emitting module 100 of FIG. 1 and FIG. 2.

The light emitting cell 220 may be configured identically as the light emitting cell 120 of FIGS. 1 and 2, except that it includes a plurality of light emitting structures 220a, 220b, and 220c.

The light emitting structures 220a, 220b, and 220c may be sequentially stacked and may emit light of different peak wavelengths from one another. FIG. 4 exemplarily illustrates that the light emitting cell 220 includes three light emitting structures 220a, 220b, and 220c, but the present invention is not limited thereto. For example, by vertically stacking light emitting structures 220a, 220b, and 220c that emit red, green, and blue light, one light emitting cell 220 may function as a single group or single pixel that implements full color. Through this, a high-efficiency, high-color reproducibility display may be implemented without an additional color filter.

As the light emitting cell 220 includes the plurality of light emitting structures 220a, 220b, and 220c, the light emitting module 200 may include a plurality of electrodes electrically connected to each of the light emitting structures 220a, 220b, and 220c. The electrodes may be electrically connected to a substrate 230 through electrode pads P.

FIG. 3 exemplarily illustrates that the light emitting module 220 includes four electrode pads P for each of the light emitting cells 220, in which at least one of the electrode pads P may be a common pad commonly connected to the plurality of light emitting structures 220a, 220b, and 220c, and some of the electrode pads P may be individual pads individually connected to each of the light emitting structures 220a, 220b, and 220c.

The substrate 230 may include a conductive pattern 235. The conductive pattern 235 may include a conductive material.

The light emitting module 200 may further include an insulation layer 290 disposed on one surface of the substrate 230 facing the light emitting cell 230. The conductive pattern 235 may be exposed through an open region of the insulation layer 290.

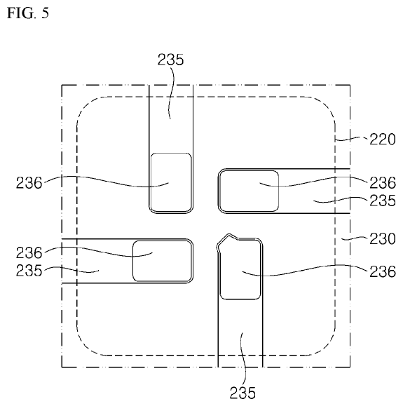

Referring to FIG. 4 and FIG. 5, the conductive pattern 235 may include a plurality of mounting portions 236 electrically connected to the light emitting cells 220. The mounting portion 236 may protrude from the conductive pattern 235. The electrode pad P of the light emitting cell 220 may be disposed on the mounting portion 236.

The plurality of mounting portions 236 may be arranged with rotational symmetry. A contact area with the light emitting cell 220 may be maximized through the mounting portion 236. In addition, a rotational symmetrical structure of the mounting portions 236 may reduce a process tolerance for a rotational direction misalignment of the light emitting cells 220 in a flip-chip bonding process. That is, even when the light emitting cell 220 is disposed in a slightly rotated state, since a stable electrical connection is possible, a yield may be improved during mass production.

A bump B may be disposed between the mounting portion 236 and the electrode pad P. The electrode pad P and the mounting portion 236 may be connected through the bump B.

The bump B may include a plurality of materials. For example, the bump B may include at least two materials among In, Al, Ti, Ni, Au, Ag, and Cu. The bump B may include a same material as a material included in an active layer of the light emitting cell 220. Through this, an effect of deformation due to thermal expansion may be minimized. In detail, coefficients of thermal expansion (CTE) of the light emitting cell 220 and the bump B become similar, mechanical stress caused by heat generated during operation may be alleviated and destruction or cracking of a joint, may be prevented, thereby ensuring long-term reliability.

The substrate 230 may include a plurality of substrate pads 232 in a peripheral region. The substrate pad 232 may be connected to the conductive pattern 235.

Optionally, the light emitting module 200 may further include an optical film layer 270 disposed on one surface of the support layer 210. The optical film layer 270 may be disposed on a surface opposite to one surface of the support layer 210 on which the light emitting cells 220 are disposed.

For example, the optical film layer 270 may be a wavelength conversion layer. The wavelength conversion layer may include a wavelength conversion material. For example, white light may be implemented when using a wavelength conversion layer including a yellow phosphor together with a light emitting cell 220 that emits blue light.

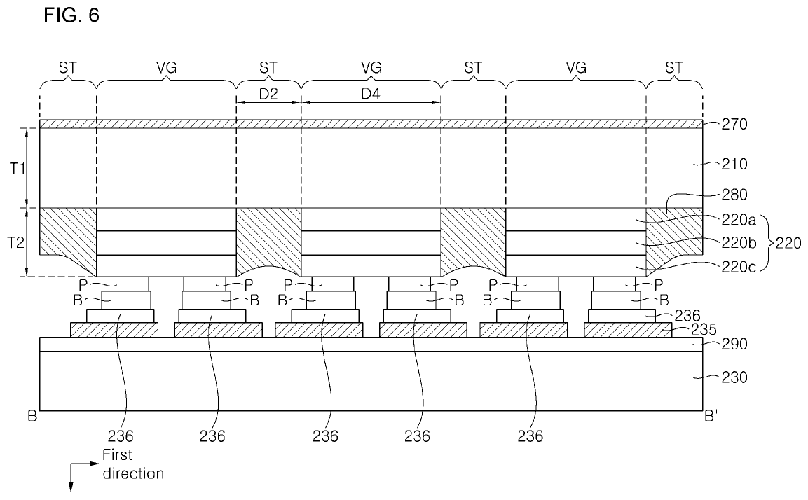

FIG. 6 is a modified example of the light emitting module 200 of FIG. 4, and in FIG. 6, the light emitting module 200 may further include a cover layer 280 as an optional configuration that fills a street region ST. A surface of the cover layers 280 that faces the substrate 230 may form a concave surface that is concavely sunken. Such a concave shape may increase a space between the concave surface of the cover layer 280 and the substrate 230, thereby increasing a heat dissipation effect using air.

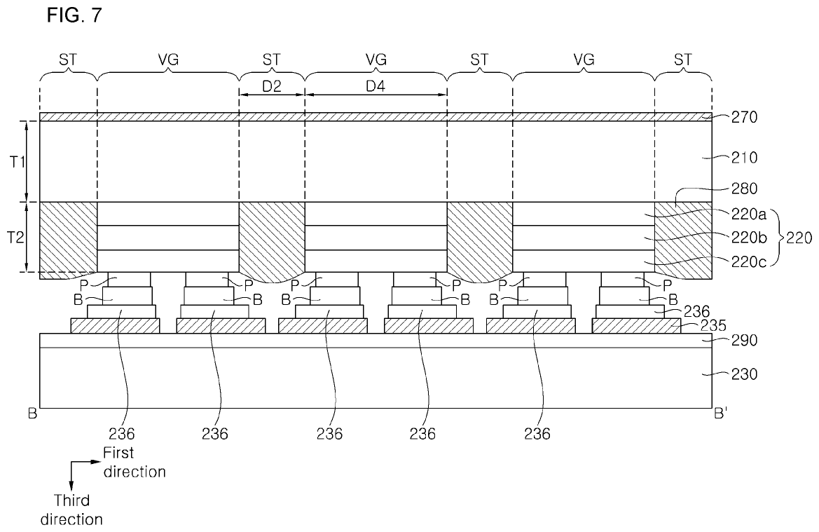

FIG. 7 is a modified example of the light emitting module 200 of FIG. 4, and may be configured identically as the light emitting module 200 of FIG. 6, except that the cover layer 280 includes a convex surface that protrudes convexly on the surface facing the substrate 230. A convex shape of the cover layer 280 may have an effect of condensing light and increasing luminance in a specific direction. Radiation characteristics suitable for an intended use may be implemented by adjusting a surface shape of the cover layer 280.

Meanwhile, the support layers 110 and 210 and the light emitting cells 120 and 220 of FIGS. 1 through 7 may have various planar shapes, and the support layers 110 and 210 may support various numbers of light emitting cells 120 and 220 having various shapes.

The support layer 110 and 210 may be configured by isolating one base substrate in which multiple light emitting cells 120 and 220 are disposed as light emitting units in various forms.

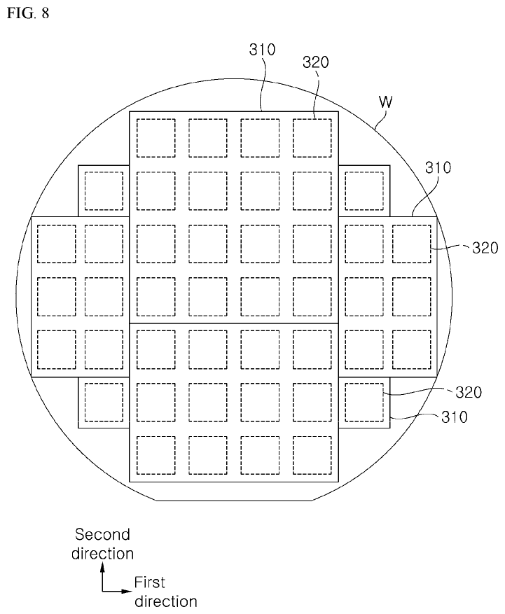

For example, FIGS. 8 through 10 illustrate various modifications of planar shapes and arrangements of the support layer 110 and 210 and the light emitting cells 120 and 220 of FIGS. 1 through 7. In FIGS. 8 through 10, W is a single base substrate on which multiple light emitting cells 120 and 220 are disposed.

First, referring to FIG. 8, multiple light emitting cells 320 may be disposed on the base substrate W. The light emitting cell 320 may include multiple sides in a polygonal shape. A support layer 310 that the base substrate W is divided may also include multiple sides in a polygonal shape. A number of sides of the support layer 310 may be same as that of sides of the light emitting cell 320.

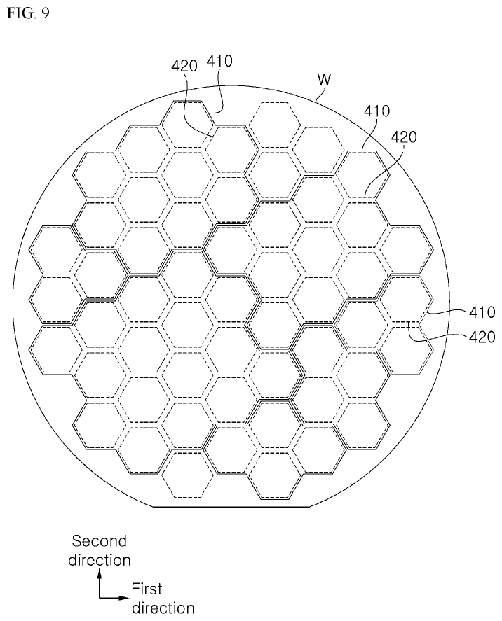

Next, referring to FIG. 9, multiple light emitting cells 420 may be disposed on the base substrate W. The light emitting cell 420 may include multiple sides in a polygonal shape. Adjacent sides of the light emitting cell 420 may meet each other at an obtuse angle. A support layer 410 that the base substrate W is divided may also include multiple sides in a polygonal shape. At least some of adjacent sides of the support layer 410 may meet each other at an obtuse angle. A number of sides of the support layer 410 may be greater than that of sides of the light emitting cell 420. Through this, a number of light emitting cells 420 disposed on the base substrate W may be maximized, and a number of support layers 410 that are generatable when the support layer 410 is formed by dividing the base material W may be maximized. That is, by using a shape that enables tessellation, such as a polygon, especially a hexagon, a region wasted during a base substrate W scribing process may be minimized, thereby reducing manufacturing costs and increasing productivity.

In addition, the support layer 410 may include protrusions and depressions on the side. Through this, a length of the side of the support layer 410 may be increased, and an amount of light emitted from the side may be increased.

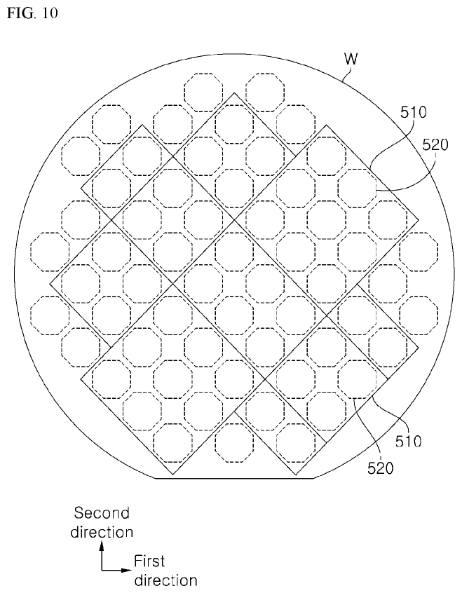

Next, referring to FIG. 10, multiple light emitting cells 520 may be disposed on the base substrate W. The light emitting cell 520 may include multiple sides in a polygonal shape. Adjacent sides of the light emitting cell 520 may meet each other at an obtuse angle. A number of sides of the light emitting cell 520 may be 7 or more. A support layer 510 that the base substrate W is divided may also include multiple sides in a polygonal shape. A number of sides of the support layer 510 may be less than that of sides of the light emitting cell 520. Through this, a number of light emitting cells 420 disposed on the base substrate W may be maximized.

A space (a portion of a street region ST) surrounded by the light emitting cells 520 may be formed on the support layer 510. Through this space, a large area for forming an electrode of the light emitting cell 520 can be secured, and electrode formation may be easily achieved. In addition, accessories such as a Zener diode, a sensor, a control apparatus, or others may be disposed in the space, thereby increasing integration and improving performance.

The light emitting modules 100, 200, 300, 400, and 500 of the present invention may be applied to various light emitting apparatuses such as lighting, displays, BLUs, vehicle lighting apparatuses, or others.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100, 200, 300, 400, 500: Light emitting module
110, 210, 310, 410, 510: Support substrate
120, 220, 320, 420, 520: Light emitting cell
130, 230: Substrate
121: First conductivity type semiconductor layer
122: Active layer
123: Second conductivity type semiconductor layer
140, 290: Insulation layer
150: First electrode
160: Second electrode
270: Optical film layer
280: Cover layer

1. A light emitting module, comprising:
a support layer; and
a plurality of light emitting cells spaced apart from one another on a surface of the support layer, wherein
the surface of the support layer includes village regions where the plurality of light emitting cells are disposed and a street region surrounding the village regions, and
a deviation in a width of the street region between adjacent village regions is within 5%.

2. The light emitting module of claim 1,
wherein the plurality of light emitting cells is disposed in an N×M matrix form.

3. The light emitting module of claim 2,
wherein the width of the street region is 50% or less of a center-to-center distance between the plurality of light emitting cells.

4. The light emitting module of claim 1,
wherein the width of the street region is 10% or less of a length of one side of a light emitting cell of the plurality of light emitting cells.

5. The light emitting module of claim 1,
wherein the width of the street region is less than a height of a light emitting cell of the plurality of light emitting cells.

6. The light emitting module of claim 1,
wherein a deviation of a maximum width of the plurality of light emitting cells is within 5%.

7. The light emitting module of claim 1,
wherein a height of the support layer is 1.5 times or more and 20 times or less than the height of a light emitting cell of the plurality of light emitting cells.

8. The light emitting module of claim 1, wherein:
a light emitting cell of the plurality of light emitting cells includes at least one light emitting structure, and
the at least one light emitting structure includes a first conductivity type semiconductor layer doped with a first conductivity type dopant, a second conductivity type semiconductor layer doped with a second conductivity type dopant, and an active layer disposed between the first conductivity type semiconductor layer and the second conductivity type semiconductor layer.

9. The light emitting module of claim 1, wherein:
a light emitting cell of the plurality of light emitting cells includes a plurality of light emitting structures that are sequentially stacked and configured to emit light of different peak wavelengths from one another, and
a light emitting structure of the plurality of light emitting structures includes a first conductivity type semiconductor layer doped with a first conductivity type dopant, a second conductivity type semiconductor layer doped with a second conductivity type dopant, and an active layer disposed between the first conductivity type semiconductor layer and the second conductivity type semiconductor layer.

10. The light emitting module of claim 8, further comprising:
an insulation layer covering the light emitting cell,
wherein the insulation layer includes a first opening exposing a partial region of the first conductivity type semiconductor layer and a second opening exposing a partial region of the second conductivity type semiconductor layer.

11. The light emitting module of claim 10, further comprising:
a first electrode connected to the first conductivity type semiconductor layer through the first opening and a second electrode connected to the second conductivity type semiconductor layer through the second opening.

12. The light emitting module of claim 11,
wherein a gap between the first electrode and the second electrode is 3 μm or more and 8 μm or less.

13. The light emitting module of claim 10,
wherein a width of the second opening is 50% or less of a maximum width of the light emitting cell.

14. The light emitting module of claim 1,
wherein a ratio of a minimum width of a light emitting cell of the plurality of light emitting cells to the width of the street region is 12.5 or more and 16.5 or less.

15. The light emitting module of claim 1, further comprising:
a substrate including a conductive pattern,
wherein the plurality of light emitting cells are disposed between the support layer and the substrate.

16. The light emitting module of claim 15,
wherein the conductive pattern includes a plurality of mounting portions electrically connected to a light emitting cell of the plurality of light emitting cells.

17. The light emitting module of claim 16,
wherein the plurality of mounting portions are disposed with rotational symmetry.

18. The light emitting module of claim 15, further comprising:
an optical film layer disposed on the surface of the support layer.

19. The light emitting module of claim 18,
wherein the optical film layer is a wavelength conversion layer.

20. A light emitting module, comprising:
a plurality of light emitting cells spaced apart from one another on a surface of a support layer, wherein
the surface of the support layer includes village regions where the plurality of light emitting cells are disposed and a street region between the village regions, and
a width of the street region is 10% or less of a length of one side of a light emitting cell of the plurality of light emitting cells.
